(19) United States
(12) Patent Application Publication
(10) Pub. No.: US 2011/0024744 A1
(43) Pub. Date: Feb. 3, 2011

(54) CONNECTION PAD STRUCTURE FOR AN ELECTRONIC COMPONENT

(75) Inventors: Pierre FEREYRE, VOREPPE (FR); Vincent HIBON, GRENOBLE (FR); Yann HENRION, FONTAINE (FR); Patrick LARIVIERE, ECHIROLLES (FR)

Correspondence Address: LOWE HAUPTMAN HAM & BERNER, LLP, 1700 DIAGONAL ROAD, SUITE 300, ALEXANDRIA, VA, 22314, US

(73) Assignee: E2V SEMICONDUCTORS, SAINT-EGREVE (FR)

(21) Appl. No.: 12/845,166

(22) Filed: Jul. 28, 2010

(30) Foreign Application Priority Data
Jul. 31, 2009 (FR) 0903795

(51) Int. Cl. H01L 23/58

(52) U.S. Cl. 257/48; 257/E23.001

(57) ABSTRACT

The invention relates to electronic components on thinned substrates, for example image sensors. Preferably, connection pads are connected through the thinned substrate to underlying layers and notably to a test pad by way of openings through which the metal of the pad passes. The openings are elongate openings extending along one edge of the pad of rectangular shape and a circular area of at least 50% (and preferably 65 to 75%) of the area of the pad contains no opening for connection with the underlying layers. This circular area is intended for bonding an external connection wire. The connection pads are testable from the back side by test probes and the front side may be tested (before bonding and thinning) by test probes with the same geometric configuration.

### RELATED APPLICATIONS

The present application is based on, and claims priority from, French Application Number 0903795, filed Jul. 31, 2009, the disclosure of which is hereby incorporated by reference herein in its entirety.

### FIELD OF THE INVENTION

The invention relates to the fabrication of electronic components on a thinned semiconductor substrate. It will be described mainly with regard to a backside illuminated image sensor on a thinned silicon substrate.

### BACKGROUND OF THE INVENTION

Image sensors on thinned substrates have been designed, in particular to improve colorimetric performance, to be illuminated from the back side of a very thin silicon layer.

The fabrication of an image sensor on a thinned substrate generally comprises the following steps: a normal silicon substrate with a thickness of a few hundred microns, allowing industrial batch handling of wafers roughly ten to twenty centimetres in diameter, is coated on the front side with an epitaxial layer of single-crystal silicon optionally isolated from the rest of the substrate by an oxide layer in the case of SOI (silicon-on-insulator) substrates. The electronic circuitry necessary for the various functions of the sensor (essentially image capture) is produced on the front side of this single-crystal layer. The substrate is then bonded, via its front side bearing this circuitry, onto a transfer substrate of sufficient thickness for industrial handling and the starting silicon substrate is thinned down to a thickness of a few microns. The resulting very small thickness of silicon precludes industrial wafer handling, and this is the reason for the presence of the bonded transfer substrate.

One of the problems posed by these components is how to form connection pads for the external connection of the component. Mounting the component in a package generally requires connecting wires to be bonded between a metal connection pad provided on the component and metal pads provided in the package.

Because the substrate in which the electronic circuits have been formed is bonded via its front side to a transfer substrate, the front side is no longer accessible. The aim is therefore to establish a connection through the back side by cutting into the thinned substrate until a conducting area, formed beforehand during the front-side fabrication steps, is reached.

Notably, the silicon and the insulating layers formed on the front side may be cut into until the first aluminium level is reached. A gold connection wire is then bonded to the exposed aluminium area with a conventional wire-bonding technique. However, this area is located within a cup since it was necessary to cut into the silicon and the insulating layers that covered it. This excludes the use of wedge bonding methods, as opposed to ball bonding methods, in which the wire to be bonded (generally made of aluminium) arrives too obliquely to be able to be bonded to the inside of a cup. This is why it is necessary to continue using gold wire bonding, even in cases where an aluminium wire would be preferred. In addition, the cup is formed in a semiconductor material and not an insulating material and there is therefore a risk of a short-circuit between the wire and the edges of the cup, unless the sidewalls of the cup are made insulating, which complicates production.

Moreover, it should also be pointed out that the aluminium areas used for the wire bonding must, in principle, be thicker than the aluminium layers that are used for ordinary interconnection functions in the integrated circuit. However, the technique explained above makes it possible in practice to gain access only to the first aluminium level (unless wishing to cut even deeper), but there is no reason for this level to be thick enough to permit bonding. To adapt this solution to an industrial operation it would therefore be necessary to provide a first aluminium level thicker than that necessary in general, something which would require changing the standard fabrication process, which is not desirable.

Additionally, the fabrication of integrated circuits requires electrical tests to be carried out by wafer probers. The test probes are applied to access pads on the integrated circuit. These pads may be provided specifically for the test, but in practice they also subsequently serve for the bonding of connection wires. It is desirable to be able to test the integrated circuit after the front-side fabrication steps, and to be able to test it again from the back side after bonding and thinning. And, if possible, it would be advantageous to be able to test the back side with the same test probe configuration used at the end of the front-side fabrication steps.

This means that it is necessary to fabricate, on the front side, test pads which have the same geometric configuration or at least the same geographical position as the external connection pads on the back side. As a result, it is necessary to fabricate, at the location of the connection pads, a superposition of at least one region of a conducting (aluminium) layer formed on the front side and constituting the test pad, and a region of another conducting layer formed on the back side and constituting the connection pad. It would even be possible to have a superposition of several metal layers formed on the front side, connected together and having the same geometry as the test pad and the connection pad.

Given that certain connection pads must be able to pass a large current (for example general power supply pads), it is arranged for the connection between the various superposed pads to be made with wide or many conducting vias between layers.

However, these multiple vias become quickly problematic because they create reliefs which can weaken the subsequent bond between a wire and the pad. The reliefs are due to the fact that the etch of the thinned silicon, to allow access to the conducting layers on the front side, is a chemical etch which forms holes with oblique sidewalls into which the aluminium descends to make contact with a conducting layer.

However, it has been realized that it is sufficient to provide a small number of conducting vias (from 1 to 4) even if it is desired to pass a large current, provided that these vias are sufficiently elongate. This is because, for a given pad metal thickness, the overall resistivity of the vias is more related to their length than to their area. This results from the fact that the metal is deposited in the vias with an almost constant thickness and it is this small metal thickness which causes an appreciable electrical resistance even when the via has a large area.

### SUMMARY OF THE INVENTION

The aim of the invention is to provide a pad configuration which makes the connection of a bonded wire with a compact pad easier and which permits the test of the connection pads from the back side with the same test probe configuration used for the front-side test.

This is why, according to the invention, an electronic component is provided comprising an integrated circuit produced on the front side of a thinned first semiconductor substrate, the thinned substrate comprising a thin semiconductor layer about 2 to 10 microns thick, the first substrate being mounted via its front side onto a transfer substrate, the component comprising:
on the front side of the first substrate a test pad formed by a region of a conducting layer deposited on the front side; and
on the back, accessible side of the semiconductor layer a pad for external connection formed from a metal layer portion deposited on this back side, superposed with the test pad and electrically connected to the test pad by way of at least one elongate opening cut through the thickness of the thinned semiconductor layer, through which opening the metal layer passes, the connection pad having a generally rectangular shape (the word ‘rectangle’ here is considered to include ‘square’) with a planar first surface portion allowing the bonding of an external connection wire and at least one second surface portion in which the elongate opening is located, characterized in that the semiconductor layer has no opening beneath the planar first surface portion and in that this first portion comprises at least one continuous part in which a circular disc occupying at least 50% of the area of the rectangle may be inscribed.

The planar first surface portion is that onto which will be bonded a connection wire when the integrated circuit chip is packaged; the conducting openings or vias are not located in this portion; the circular part of this area represents the area available in practice for fixing the wire whilst correctly centering the wire on the pad. The resulting pad configuration is a compact pad configuration. This configuration ensures that the recessed reliefs resulting from etching the vias between the connection pad and the underlying layers do not cause problems with the subsequent bonding of a connection wire. This configuration allows the superposition, without excessive bulk, of the test pad and the connection pad, and therefore allows probe testing with the same probe configuration for the front-side and back-side tests.

As will be seen, several practical configurations may be adopted in accordance with the invention, and notably one of the following preferred configurations:
the pad has a somewhat rectangular shape, with one side between 5 and 20% longer than the other, the elongate opening extending along a shorter side of the rectangle, parallel to this side; the continuous circular part may then occupy typically 75% to 65% of the area of the rectangle; or, the opening extends along the two short sides of the rectangle, parallel to these sides, and the circular part may occupy from 65% to 70% of the area of the rectangle;
the pad has a square shape and the elongate opening extends along two adjacent sides of the square, parallel to these sides; the circular part may then occupy from 60% to 70% of the area of the pad; the width of the elongate opening is preferably between 2% and 9% of the side length of the square;
the pad has a square shape and the elongate opening is distributed along the four adjacent sides of the square, parallel to these sides; the circular part may occupy an area of 55% to 65% that of the rectangular pad; the width of the elongate opening is preferably between 1% and 5% of the side length of the square; and
the pad has a square shape and the elongate opening is distributed over four separate portions each one located in a respective corner of the square, the circular part may occupy from 55% to 65% of the pad.

Still other objects and advantages of the present invention will become readily apparent to those skilled in the art from the following detailed description, wherein the preferred embodiments of the invention are shown and described, simply by way of illustration of the best mode contemplated of carrying out the invention. As will be realized, the invention is capable of other and different embodiments, and its several details are capable of modifications in various obvious aspects, all without departing from the invention. Accordingly, the drawings and description thereof are to be regarded as illustrative in nature, and not as restrictive.

### BRIEF DESCRIPTION OF DRAWINGS

The present invention is illustrated by way of example, and not by limitation, in the figures of the accompanying drawings, wherein elements having the same reference numeral designations represent like elements throughout and wherein:

FIG. 1 shows a cross section of an integrated circuit structure on a thinned substrate, with a connection pad, provided with vias distributed beneath the pad connecting the pad to underlying conducting layers;

FIG. 2 shows a top view of the connection pad of FIG. 1;

FIG. 3 shows a cross section of a pad structure according to the invention; and

FIGS. 4 to 8 show, a top view of several connection pad configurations according to the invention.

### DESCRIPTION OF PREFERRED EMBODIMENTS

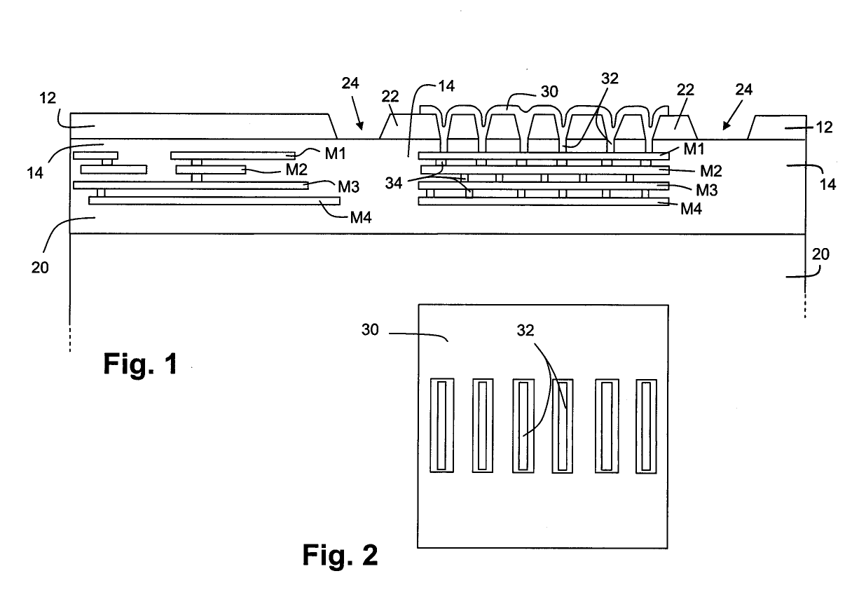

FIGS. 1 and 2 show a possible exemplary structure for a connection pad of an electronic component. The electronic component is an integrated circuit formed in a thinned semiconductor substrate 12 bonded onto a transfer substrate 20. The substrate is, in principle, made of silicon. The component may be notably an image sensor intended to be illuminated through the back side of the thinned substrate.

The back side is facing upwards in FIG. 1, the front side is facing downwards. In the fabrication process there are firstly front-side fabrication steps, notably steps of doping, depositing and etching insulating, conducting and semiconducting layers, then bonding of the semiconductor substrate via its front side onto the transfer substrate 20, then a thinning of the semiconductor substrate 12 from its back side until a semiconductor thickness of a few microns, typically from 2 to 5 microns, is reached and finally back-side fabrication steps. FIG. 1 shows a schematic cross section of the component at this stage of the fabrication. After the back-side treatment steps, it remains to mount the component in a package by bonding connecting wires between connection pads of the component and pads of a package.

In the front-side fabrication steps, an alternation of several levels of conducting (in general metal, for example aluminium) and insulating (in general silicon oxide) layers are notably formed. The various conducting layers are etched to define patterns of internal connections in the integrated circuit; the insulating layers are etched to define openings enabling conducting vias to be established between the conducting layers of the various levels, depending on the connections required between these layers. An insulating passivation layer covers all the metal levels; this layer has a planar surface in close contact with the transfer substrate 20.

The metal conducting layers are denoted by the references M1, M2, M3, M4 in the order in which they are deposited on the semiconductor substrate during the treatment of the front side; it will be noted that the first layer deposited is M1 and the last is M4, knowing that the substrate 12 is shown upside down in FIG. 1.

The set of insulating layers in which the metallic layers M1 to M4 are embedded is denoted by the reference 14.

The right-hand side of FIG. 1 shows a possible construction of a connection pad 30 of the component. It is formed principally from a metal layer (in principle made of aluminium) deposited and etched on a portion 22 of the semiconductor substrate. The metal is deposited from the back side of the substrate. The portion 22 is electrically isolated from the rest of the substrate 12 by a trench 24 which completely surrounds this portion. This trench is cut from the back side right through the thickness of the thinned semiconductor substrate 12, down to the insulating layer 14.

The connection pad 30 is electrically connected to the underlying integrated circuit, and more precisely to at least one of the conducting layers M1 to M4, through conducting vias 32 distributed beneath the area of the pad. The conducting vias are openings passing right through the thickness of the thinned substrate 12 and through a part of the thickness of the insulating layer 14 to reach a conducting layer formed from the front side. These openings are filled with metal (aluminium) deposited to form the pad 30. In the example shown, the conducting vias 32 make physical contact with the first conducting layer M1, and portions of layers M1, M2, M3 and M4 are located below the pad 30 and have substantially the same geometry and the same horizontal position as the pad 30. These layers are connected together by other conducting vias 34 distributed over the extent of the area corresponding to this geometry.

FIG. 2 shows a top view of a possible configuration of the conducting vias 32 distributed over the area of the connection pad 30.

The presence of conducting vias creates a relief in the surface of the pad, especially when the silicon substrate is etched with a liquid etchant. This relief essentially comprises recesses centred on the conducting vias. If the vias are elongate, the recessed areas follow the long direction.

These recesses may impair the quality of the bonding of the connection wire that will be bonded to the pad.

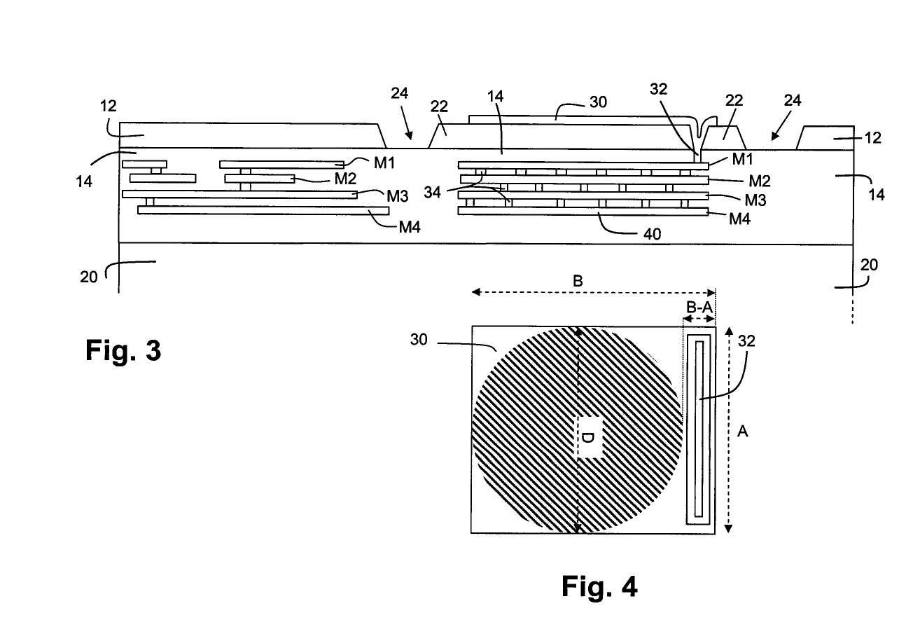

FIGS. 3 and 4 show a component having a pad structure according to the present invention.

The conducting openings or vias distributed beneath the area of the pad are replaced, in this embodiment, by a single elongate via 32 extending over almost the entire length of one side of the pad. The pad is somewhat rectangular with a short side of length A and a long side of length B. The via extends along a short side. It may therefore be considered that the pad comprises a square first surface portion of side length A which has a completely planar surface, containing no conducting vias, and a rectangular second surface portion of width B−A and of length A which is not uniformly planar and which has a recessed relief due to the via.

The planar square surface portion is reserved for the bonding of a connection wire, and it may be considered that in this square area is inscribed a circular disc of diameter D=A (shown cross-hatched in the figure) which is more precisely reserved for bonding the wire and which must be large enough to allow such bonding to be reliable and reproducible.

According to the invention, the pad is constituted so that the area Sc of the circular disc (Sc=πD²/4) inscribed in the planar surface and available for wire bonding occupies at least 50% and preferably between 60% and 75% of the total area St of the rectangular pad (St=A×B).

Preferably, in the configuration of FIG. 4, the width B−A of the residual area available for lodging the elongate via extends over a width equal to about 5% to 20% of the short side A of the pad. The pad occupies then an area 5% to 20% greater than the area (A²) of a square pad with vias located entirely beneath the circular bonding zone.

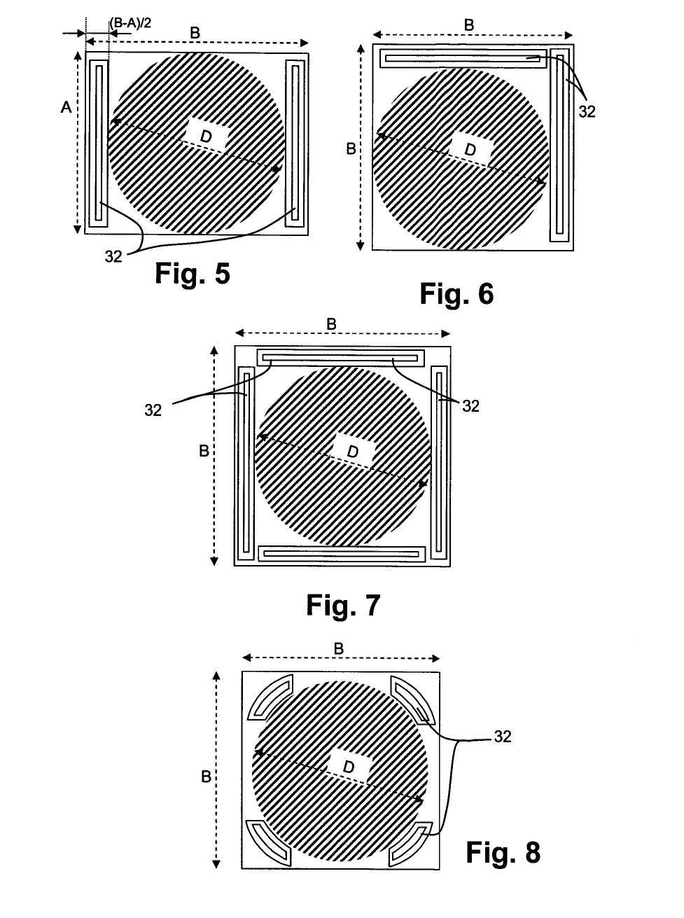

If it is necessary to pass still more current through the conducting via a configuration with two elongate vias may be adopted, as shown either in FIG. 5 (an elongate via along the edge of each of the two short sides of the rectangular pad) or in FIG. 6 (a respective elongate via along two adjacent sides of a square pad).

In the configuration of FIG. 5, the pad area is preferably chosen such that the area Sc of the circular disc occupies between 65% and 70% of the area St of the pad and, to do this, the residual width of each side for lodging a respective via will be (B−A)/2, equal to about 5% to 10% of the value A of the short side of the pad. The pad then occupies an area from 10% to 20% greater than that which it would occupy if the vias were located beneath the bonding zone.

In the configuration of FIG. 6, the pad is square, A=B, and D is less than A; the pad area is preferably arranged such that the area Sc of the circular disc (St=πD²/4) occupies between about 60% and 70% of the area of the pad St=B²; to do this, the residual width B−D for lodging the vias is about 5% to 14% of the diameter D.

The vias are shown separated in FIG. 6, but they could possibly be joined at their adjacent corner.

If the narrow via lengths are still not sufficient it may furthermore be tried to place a via on three or four sides of the pad, the centre of the pad containing the disc reserved for bonding. FIG. 7 shows a configuration with four elongate vias each one along one side of the pad. The pad is a square of side length B greater than the diameter D of the disc. The width reserved for the vias is (B−D)/2 and it is arranged that this width is about 5 to 10% of D; the circular area reserved for the disk is then 55% to 65% of the area of the pad.

In all the configurations of FIGS. 4 to 7 the elongate vias occupy practically the entire length of one side of the pad.

Finally, FIG. 8 shows a solution that best uses the corners of the pad. The elongate conducting vias are not parallel to the sides of the pad (which is preferably square) but are rather lodged in the corners, in the space left free outside a circle of is diameter D. The side length B is slightly greater than the diameter D. The area St of the disc of diameter D is then preferably between 55% and 65% of the area of the pad. In the drawing of FIG. 8, the vias have a rounded shape extending parallel to the circular area; they might also have an L or triangular shape.

The connection pad of FIG. 3, having in top view one of the configurations of FIGS. 4 to 8, preferably overhangs metal lands having substantially the same area and the same horizontal position as the pad 30. The metal lands are formed in the various conducting layers M1 to M4 and are electrically connected by the vias 34 as shown in FIG. 1. The vias 34 may be distributed over the entire area of these lands and may be numerous and of very small size. This is because the vias are etched in insulating layers by processes that do not create openings with slanting sidewalls (unlike the silicon etch) in any case they are not used to bond a connection wire.

During the fabrication, these metal lands in the form of pads may be used as test pads for probe test operations. In particular, the conducting layer M4 preferably comprises a region constituting a test pad 40 allowing a test after the completion of the front-side fabrication steps, before the deposition of an insulating passivating planarization layer on the front side. Given connection pads and test pads with identical geometry, the test probe configuration may be the same for the front-side and back-side tests (with the proviso that the chip assembly has symmetrically placed pads).

Shown in the configuration of FIG. 2 is a connection pad 30 that overhangs the metal lands. It could also be possible to use a configuration in which the pad is partly offset laterally with respect to the metal lands or to the test pad (the connection via 32 of course remaining above the metal land with which it must make contact). This does not stop the test probe configuration from being the same for the front side and the back side, for example by arranging for all the pads to be offset in the same direction by the same amount.

It will be readily seen by one of ordinary skill in the art that the present invention fulfils all of the objects set forth above. After reading the foregoing specification, one of ordinary skill in the art will be able to affect various changes, substitutions of equivalents and various aspects of the invention as broadly disclosed herein. It is therefore intended that the protection granted hereon be limited only by definition contained in the appended claims and equivalents thereof.

1. Electronic component comprising an integrated circuit produced on a front side of a thinned first semiconductor substrate, the thinned substrate comprising a thin semiconductor layer about 2 to 10 microns thick, the first substrate being mounted via its front side onto a transfer substrate, the component comprising:
on the front side of the first substrate a test pad formed by a region of a conducting layer deposited on the front side; and
on a back, accessible side of the semiconductor layer a connection pad for external connection, formed from a metal layer portion deposited on this back side, superposed with the test pad and electrically connected to the test pad by way of at least one elongate opening cut right through the thickness of the thin semiconductor layer, through which opening the metal layer passes, the connection pad having a generally rectangular shape with a planar first surface portion allowing the bonding of an is external connection wire and at least one second surface portion in which the elongate opening is located, wherein the semiconductor layer has no opening beneath the planar first surface portion and wherein this first portion comprises at least one continuous part in which a circular disc occupying at least 50% of the area of the rectangle may be inscribed.

2. Electronic component according to claim 1, wherein the connection pad has a generally rectangular shape, with a long side between 5 and 20% longer than the short side, the elongate opening extending along the short side of the rectangle, parallel to the short side.

3. Electronic component according to claim 1, wherein the connection pad has a rectangular shape and the area of the circular part occupies 75% to 65% of the area of the rectangle.

4. Electronic component according to claim 1, wherein the connection pad has a rectangular shape, with long sides between 5 and 20% longer than short sides, the elongate opening extending along the two short sides of the rectangle, parallel to the short sides.

5. Electronic component according to claim 1, wherein the connection pad has a rectangular shape, the elongate opening extending along two short sides of the rectangle, parallel to these sides, and the area of the circular part occupies from 65 to 70% of the area of the rectangle.

6. Electronic component according to claim 1, wherein the connection pad has a square shape and the elongate opening extends along two adjacent sides of the square, parallel to these sides, with a width of between 2% and 9% of the side length of the square.

7. Electronic component according to claim 1, wherein the connection pad has a square shape and the elongate opening extends along two adjacent sides of the square, parallel to these sides, and the area of the circular part occupies between 60% and 70% of the area of the pad.

8. Electronic component according to claim 1, wherein the elongate opening is distributed along the four adjacent sides of the square, parallel to these edges, with a width of between 1% and 5% of the side length of the square.

9. Electronic component according to claim 1, wherein the elongate opening is distributed along the four adjacent sides of the square, parallel to these sides, and the area of the circular part occupies from 55% to 65% of the area of the pad.

10. Electronic component according to claim 1, characterized in that the pad has a square shape and the elongate opening is distributed over four separate portions each one located in a respective corner of the square, the circular part occupying from 55% to 65% of the area of the pad.
